(19) United States
(12) Patent Application Publication
(10) Pub. No.: US 2008/0169538 A1
(43) Pub. Date: Jul. 17, 2008

(54) Semiconductor Device

(75) Inventors: Yasumasa Kasuya, Kyoto (JP); Motoharu Haga, Kyoto (JP); Shoji Yasunaga, Kyoto (JP)

Correspondence Address: FISH & RICHARDSON P.C., P.O. BOX 1022, MINNEAPOLIS, MN, 55440-1022, US

(73) Assignee: Rohm Co., Ltd., Kyoto (JP)

(21) Appl. No.: 11/972,945

(22) Filed: Jan. 11, 2008

(30) Foreign Application Priority Data
Jan. 15, 2007 (JP) 2007-005407

(51) Int. Cl. H01L 23/495

(52) U.S. Cl. 257/669; 257/E23.053

(57) ABSTRACT

A semiconductor device of the present invention includes a semiconductor chip, a die pad to which the semiconductor chip is bonded with solder to be mounted thereon, a plurality of leads electrically conducted to the semiconductor chip, a stress reducing layer that is provided on a rear face of the die pad opposite to a face of the die pad on which the semiconductor chip is mounted and that reduces stress applied to the semiconductor chip, and a sealing body for sealing at least the semiconductor chip.

This application is based on Japanese Patent Application No. 2007-005407 filed on Jan. 15, 2007, the contents of which are hereby incorporated by reference.

### BACKGROUND OF THE INVENTION

1. Field of the Invention

The present invention relates to a semiconductor device, and in particular to the configuration of a semiconductor device formed by bonding a semiconductor chip to a die pad with solder.

2. Description of Related Art

In power semiconductor devices provided with a semiconductor chip such as a power transistor and a power IC, as shown in Patent Publication 1, when the semiconductor chip is fixed onto a die pad (also called an island) of a lead frame, the bonding (die bonding) is performed with solder.

FIGS. 7A and 7B are schematic diagrams illustrating disadvantages in die bonding with solder a semiconductor chip to a die pad formed with, e.g., Cu alloy. Here, FIG. 7A shows how members are laid on top of each other in a heated state to be bonded together with solder, and FIG. 7B shows the state where the bonding between the semiconductor chip and the die pad with solder is completed and the temperature is lowered to a predetermined temperature.

Since Si, which forms the semiconductor chip (Si chip) 101, has a small thermal expansion coefficient of, for example, 3 to 4 ppm/K in the temperature range where the bonding with the solder 102 is performed (e.g., a range between room temperature and 350° C.), the semiconductor chip 101 does not shrink very much with the decrease of temperature after the solder bonding, and thus is not distorted (warped) by a very large amount. In contrast, since the Cu alloy, which forms the die pad 103, has a large thermal expansion coefficient of, for example, approximately 17 ppm/K in the temperature range where the bonding with the solder 102 is performed, the die pad 103 is warped by a large amount as shown in FIG. 7B when the temperature is lowered after the solder bonding. Due to the warp of the die pad 103, stress is applied to the semiconductor chip 101, and this causes damage to the semiconductor chip 101 such as a crack.

A conventional method of coping with this problem is to increase the thickness of solder used for bonding a semiconductor chip and a die pad together. With this method, the solder layer reduces the stress applied to the semiconductor chip due to the difference in thermal expansion coefficient between the semiconductor chip and the die pad, and thus damage to the semiconductor chip can be reduced. Another conventional method of preventing damage to a semiconductor chip is to increase the thickness of a die pad when the semiconductor chip and the die pad are bonded. With this method, warp of the die pad caused by the decrease of temperature after solder bonding can be reduced, and thus the stress applied to the semiconductor chip can also be reduced.

However, taking into consideration that the recent trend is toward thin-packaged semiconductor devices, and that this trend will lead to the development of a thin-packaged semiconductor device formed with a thin lead frame, the conventional method in which the thickness of the die pad is increased is not advisable, because it results in an increase in thickness of the lead frame. In addition, in the case where the thickness of a lead frame is increased in order to make a die pad thicker, the lead frame is difficult, for example, to bend, and this makes the fabrication of the semiconductor device inconveniently difficult.

In the method in which the stress applied to a semiconductor chip is reduced by increasing the thickness of a solder layer provided for bonding a semiconductor chip and a die pad together, the thickness of the solder layer is difficult to control and varies. In this case, if the solder layer is thin, the stress applied to the semiconductor chip due to the distortion of the die pad cannot be effectively reduced, and thus the semiconductor chip is damaged. Therefore, the method in which a semiconductor chip is protected from damage by increasing the thickness of a solder layer is unreliable, and thus is not an adequate method.

### SUMMARY OF THE INVENTION

In view of the above described problems, an object of the present invention is to provide a semiconductor device including a semiconductor chip bonded to a die pad with solder in which damage to the semiconductor chip can be reduced with a high degree of accuracy, and with which a thin package can be realized.

To achieve the object described above, according to one aspect of the present invention, a semiconductor device includes: a semiconductor chip; a die pad to which the semiconductor chip is bonded with solder to be mounted thereon; a plurality of leads electrically conducted to the semiconductor chip; a stress reducing layer that reduces stress applied to the semiconductor chip and is provided on a rear face of the die pad opposite to a face of the die pad on which the semiconductor chip is mounted; and a sealing body for sealing at least the semiconductor chip.

With this configuration, when the semiconductor chip is bonded to the die pad with solder, the stress reducing layer can reduce the warp of the die pad occurring due to its shrinking when it is cooled after the bonding. With this configuration, it is possible to reduce the thickness of a package-type semiconductor device more than with a method in which the thickness of a die pad itself is increased to reduce the warp of the die pad. With this configuration, since the stress reducing layer is disposed on the rear face of the die pad to reduce the stress applied to the semiconductor chip, it is possible to reduce the stress applied to the semiconductor chip with a higher degree of accuracy than with a method in which the thickness of a solder layer is increased to reduce the stress applied to the semiconductor chip.

According to the present invention, in the semiconductor device configured as described above, the stress reducing layer may be bonded to the rear face of the die pad via a solder layer. In this case, since the same bonding material is used to bond the semiconductor chip to the die pad and the die pad to the stress reducing layer, the fabrication process of a semiconductor device is prevented from becoming complex.

According to the present invention, in the semiconductor device configured as described above, it is preferable that the stress reducing layer be formed of a material having a smaller thermal expansion coefficient than a main material forming the die pad has. With this configuration, the stress reducing layer can reduce the warp of the die pad due to the die pad shrinking when it is cooled after the solder bonding, and thereby the stress applied to the semiconductor chip can be reduced.

According to the present invention, in the semiconductor device configured as described above, it is preferable that the stress reducing layer be formed of a material having a same or a substantially same thermal expansion coefficient as a main material forming the semiconductor chip has. In this case, the stress reducing layer can reduce more effectively the warp of the die pad due to the die pad shrinking when it is cooled after the bonding, and thereby the stress applied to the semiconductor chip can be reduced more effectively.

To achieve the above object, according to another aspect of the present invention, a semiconductor device includes: a semiconductor chip; a die pad to which the semiconductor chip is bonded with solder to be mounted thereon; a plurality of leads electrically conducted to the semiconductor chip; a stress reducing layer that is laid in a solder layer and is formed of a material having a thermal expansion coefficient that is smaller than a thermal expansion coefficient of a main material forming the die pad and is same or substantially same as a thermal expansion coefficient of a main material forming the semiconductor chip; and a sealing body for sealing at least the semiconductor chip.

With this configuration, when the semiconductor chip is bonded to the die pad, the stress reducing layer can reduce the stress applied to the semiconductor chip due to the difference in shrinkage ratio between the die pad and the semiconductor chip. Also, with this configuration, it is possible to reduce the thickness of a package-type semiconductor device more than with a configuration in which the thickness of a die pad itself is increased to reduce the warp of the die pad. Furthermore, since the stress reducing layer is laid in the solder layer, it is possible to reduce the stress applied to the semiconductor chip with a higher degree of accuracy than with a configuration in which the thickness of the solder layer bonding a semiconductor chip and a die pad together is increased to reduce the stress applied to the semiconductor chip. Moreover, with this configuration, since the stress reducing layer is disposed on the same side as the semiconductor chip with respect to the die pad, the fabrication of a semiconductor device can be facilitated.

As described above, according to the present invention, in a semiconductor device in which a semiconductor chip is bonded to a die pad, it is possible to reduce the stress applied to the semiconductor chip by use of a stress reducing layer without increasing the thickness of a lead frame (including the die pad) and a solder layer. This makes it possible to provide a highly reliable semiconductor device in which a semiconductor chip hardly suffers from damage such as cracks. Furthermore, with the semiconductor device of the present invention, since damage to a semiconductor chip can be reduced while the thickness of a die pad on which the semiconductor chip is mounted is reduced, a thin compact package-type semiconductor device can be easily realized.

### BRIEF DESCRIPTION OF THE DRAWINGS

FIG. 1 is schematic plan view showing the configuration of a semiconductor device of a first embodiment;

FIG. 2 is a schematic sectional view taken along line II-II of FIG. 1;

FIG. 3 is a schematic plan view showing the configuration of a lead frame used when the semiconductor device of the first embodiment is fabricated;

FIG. 4 is a diagram showing a modified example of the semiconductor device of the first embodiment;

FIG. 5 is a sectional view taken along line V-V of FIG. 4;

FIG. 6 is a schematic sectional view showing the configuration of a semiconductor device of a second embodiment;

FIG. 7A is a diagram illustrating inconveniences experienced with conventional semiconductor devices and showing how members are laid on top of each other in a heated state to be bonded together with solder; and

FIG. 7B is a diagram illustrating inconveniences experienced with conventional semiconductor devices and showing the state where the bonding between a semiconductor chip and a die pad with solder is completed and the temperature is lowered to a predetermined temperature.

### DETAILED DESCRIPTION OF PREFERRED EMBODIMENTS

Preferred embodiments of the present invention will hereinafter be described with reference to the attached drawings. It should however be understood that the embodiments presented below are merely examples, and are therefore not meant to limit the semiconductor device of the present invention in any way.

### First Embodiment

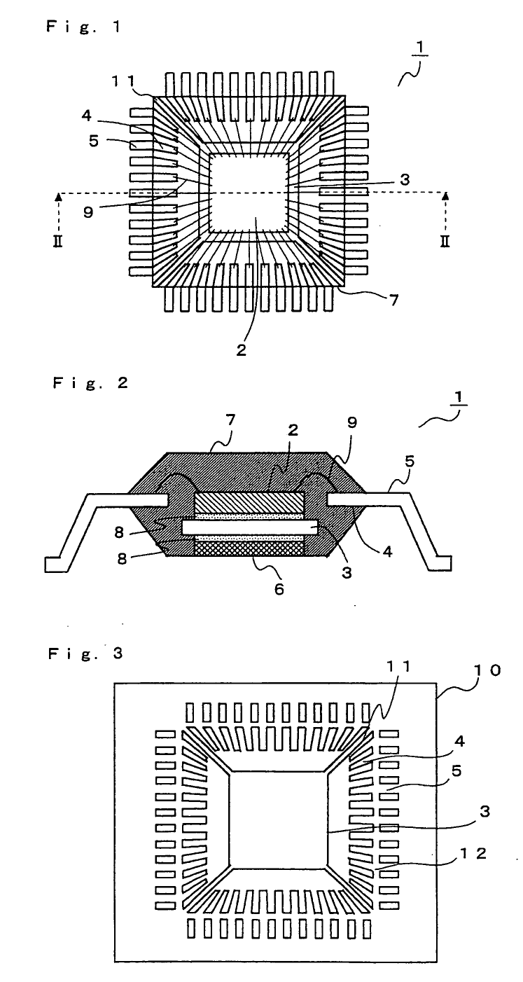

First, a semiconductor device of a first embodiment of the present invention will be described with reference to FIGS. 1, 2, and 3. FIG. 1 is a schematic plan view showing the configuration of the semiconductor device of the first embodiment. FIG. 1 is a diagram of the semiconductor device as viewed from the side on which a semiconductor chip is mounted, and for convenience of illustration, sealing resin for sealing the semiconductor chip, etc. is assumed to be transparent. FIG. 2 is a schematic sectional view showing the configuration of the semiconductor device of the first embodiment, and is taken along line II-II of FIG. 1. FIG. 3 is a schematic plan view showing the configuration of a lead frame used when the semiconductor device of the first embodiment is fabricated.

The semiconductor device 1 of the first embodiment is a semiconductor device having a so-called quad flat package (QFP), which is a type of surface-mount package. As shown in FIGS. 1 and 2, the semiconductor device 1 includes a semiconductor chip 2, a die pad 3, inner leads 4, outer leads 5, a stress reducing layer 6, and a sealing body 7.

The semiconductor chip 2 is formed of a silicon substrate having a substantially rectangular shape as viewed in plan, and there is formed, for example, a power IC in its surface. In this embodiment, the thickness of the semiconductor chip 2 is, for example, approximately 300 μm. The semiconductor chip 2 is bonded to the die pad 3 to be mounted thereon.

The die pad 3 is formed such that it is substantially rectangular as viewed in plan and its plan size is larger than that of the semiconductor chip 2. This die pad 3 is, as described above, a portion to which the semiconductor chip is bonded to be mounted thereon, and is punch-formed in a lead frame 10 that is used when the semiconductor device 1 is fabricated. From each of the four corners of the die pad 3, a support bar 11 extends, and the die pad 3, being supported by the support bars 11, is offset downward with respect to the other parts of the lead frame 10. Thus, in the semiconductor device 1, as shown in FIG. 2, the die pad 3 is located below the inner leads 4. The lead frame 10, in which the die pad 3 and the like are formed, is formed with, for example, Cu alloy. The thickness of the die pad 3 is, for example, approximately 100 to 150 μm.

The semiconductor chip 2 and the die pad 3 are bonded together with solder, and a solder layer 8 exists between the semiconductor chip 2 and the die pad 3. In this embodiment, as the solder, for example, high-melting-point solder (Pb-5% Sn) is used, but needless to say, solder of different composition (e.g., Pb-free solder) may be used.

A plurality of the inner leads 4 are provided around the die pad 3, and electrically connected to a terminal pad formed on a top face of the semiconductor chip 2 via metal wires such as gold wires. The outer leads 5 are continuous with the inner leads 4 and extend outside the sealing body 7 from the side portion of the sealing body 7. The outer leads 5 each have part thereof bent, and thereby the semiconductor device 1 can be surface-mounted on a printed board (not shown).

The stress reducing layer 6 has a function to reduce the stress that occurs due to the difference in thermal shrinkage ratio between the semiconductor chip 2 and the die pad 3 and is applied to the semiconductor chip 2 when the semiconductor chip 2 and the die pad 3 are bonded together with solder. This stress reducing layer 6 is bonded with solder to a rear face of the die pad 3 opposite to the face to which the semiconductor chip 2 is bonded. Hence, a solder layer 8 exists between the die pad 3 and the stress reducing layer 6. In the semiconductor device 1 of this embodiment, the stress reducing layer 6 is formed of a 42 alloy material (Fe-42% Ni alloy), and is approximately 100 to 150 μm thick.

In this embodiment, the size of the bonding face between the stress reducing layer 6 and the die pad 3 is substantially equal to that of the bonding face between the semiconductor chip 2 and the die pad 3. However, this is not meant to be a limitation, and the size can be suitably changed as necessary. That is, the size of the bonding face between the stress reducing layer 6 and the die pad 3 may be changed as necessary in the range where the provision of the stress reducing layer 6 helps reduce the stress applied to the semiconductor chip 2.

The sealing body 7 is formed of sealing resin such as epoxy resin, and prevents the semiconductor chip 2 from being affected by the ambient atmosphere (gas, moisture, dust, etc.). In the semiconductor device 1, the sealing body 7 covers up the semiconductor chip 2, the die pad 3, and the inner leads 4; with respect to the stress reducing layer 6, the bottom face of the stress reducing layer 6 is flush with that of the sealing body 7 and is exposed. The bottom face of the stress reducing layer 6 is exposed as described above for the purpose of, for example, facilitating dissipation of heat generated by the semiconductor chip 2 via the die pad 3 and the stress reducing layer 6. In particular, it is advisable that the semiconductor chip 2, which is a power semiconductor chip such as a power IC be provided with a mechanism for dissipating heat, because it generates comparatively large amount of heat.

Next, a description will be given of a fabrication method of the semiconductor device 1 configured as described above. The fabrication method of the semiconductor device 1 that will be described here is only an example, and needless to say, the semiconductor device 1 may be fabricated by use of any other method.

First, the lead frame 10 having the shape as shown in FIG. 3 is formed by pressing. In the lead frame 10, the reference numeral 3 denotes the die pad, the reference numeral 4 denotes the inner leads, the reference numeral 5 denotes the outer leads, the reference numeral 11 denotes the support bars, and the reference numeral 12 denotes tie bars arranged between the inner leads 4 and the outer leads 5 to support this group of leads. When these parts are formed by pressing, the die pad 3 supported by the support bars 11 is pressed down by a predetermined amount so that the bottom face of the stress reducing layer 6 is flush with that of the sealing body 7 and is exposed when the package-type semiconductor device 1 is formed.

Then, solder is supplied to a top face (a face which is bonded to the die pad 3) of the 42 alloy material that is processed into a predetermined shape to be the stress reducing layer 6, and heat is applied (e.g., at a temperature approximately 350° C.) to melt the solder. Then, on top of the molten solder, the lead frame 10 is placed in a predetermined position so that the die pad 3 and the 42 alloy material forming the stress reducing layer 6 overlap each other, and then the die pad 3 and the 42 alloy material are fixedly bonded together by application of pressure or by other methods.

Then, in the heated state, solder is supplied to a top face (a face opposite to the face that is fixedly bonded to the 42 alloy material) of the die pad 3, and thus molten solder is formed. Then, the semiconductor chip 2 is placed on the molten solder, and the die pad 3 and the semiconductor chip 2 are fixedly bonded together by application of pressure or by other methods. Then, the lead frame 10, on which the stress reducing layer 6 and the semiconductor chip 2 are mounted, is cooled down to a predetermined temperature. In this way, the semiconductor chip 2 and the stress reducing layer 6 are bonded to the die pad 3. The above described bonding with solder is performed in an atmosphere of, for example, nitrogen gas.

Then, the inner leads 4 are electrically connected to the terminal pad formed on the top face of the semiconductor chip 2 via the fine metal wires 9. Then, the semiconductor chip 2, the die pad 3, the inner leads 4, and the stress reducing layer 6 are covered with the sealing resin (more precisely, the bottom face of the stress reducing layer 6 is not covered with the resin as described above), for example, by a transfer-mold method using a mold, and thus the sealing body 7 is formed.

Lastly, unwanted parts of, for example, the tie bars 12 and the support bars 11 projecting from the sealing body 7 are cut off and removed, and the outer leads 5 that are continuous with the inner leads 4 and disposed outside the sealing body 7 are each bent into a predetermined shape, and thus the fabrication of the semiconductor device 1 is completed.

In the above description, the 42 alloy material forming the stress reducing layer 6 is bonded with solder, but metal other than solder may be used to perform bonding at a high temperature. In some cases, it is possible to fit the stress reducing layer 6 to the die pad 3 by a method such as welding and ultrasonic bonding when the lead frame 10 is formed. However, since the semiconductor chip 2 and the die pad 3 are bonded together with solder in the semiconductor device 1, it is preferable, in view of facilitation of the fabrication of the semiconductor device 1, that the die pad 3 and the stress reducing layer 6 are bonded together with solder as in this embodiment.

Next, a description will be given of the operation of the semiconductor device 1. In the semiconductor device 1 of this embodiment, the die pad 3 is formed as thin as approximately 100 to 150 μm thick as described above. In this case, the thermal expansion coefficient of the Cu alloy forming the die pad 3 is as large as approximately 17 ppm/K in the temperature range where the solder bonding is performed (e.g., from room temperature to 350° C. or less); therefore, the die pad 3 is liable to suffer from a large warp due to thermal shrinkage after the die-bonding of the semiconductor chip 2 with solder is performed.

To cope with this, in the semiconductor device 1, on the rear face of the die pad 3 that is opposite to the face of the die pad 3 on which the semiconductor chip 2 is formed, the stress reducing layer 6 is formed that is formed of the 42 alloy material whose thermal expansion coefficient is, for example, 5 to 7 ppm/K in the temperature range where the bonding with solder is performed (e.g., room temperature to 350° C.). The thermal expansion coefficient of this stress reducing layer 6 is close to that of Si (e.g., 3 to 4 ppm/K), and is quite smaller than that of the Cu alloy mainly forming the die pad 3. Therefore, the stress reducing layer 6 is distorted only by a small amount after the solder bonding, and thus the warp of the die pad 3 can be reduced. This makes it possible to reduce the stress applied to the semiconductor chip 2.

Furthermore, the semiconductor device 1 is configured such that the stress reducing layer 6 is additionally provided on the rear face of the die pad 3 that is opposite to the face of the die pad 3 on which the semiconductor chip 2 is provided. Thus, with the semiconductor device 1, it is possible to reduce the stress applied to the semiconductor chip with a higher degree of accuracy than with a semiconductor chip having a configuration in which the thickness of a solder layer is increased to reduce the stress applied to the semiconductor chip (in this case, as mentioned above, it is difficult to form the solder layer having a predetermined thickness with a high degree of accuracy).

Moreover, in order to effectively reduce the stress applied to the semiconductor chip 2 due to the solder bonding by increasing the thickness of the die pad 3 (the lead frame 10), the thickness of the die pad 3 needs to be, for example, approximately 500 μm. In contrast, with the semiconductor device 1 of this embodiment, when the thickness of the die pad 3 is, for example, approximately 100 to 150 μm, the stress applied to the semiconductor chip 2 can be effectively reduced by making the stress reducing layer 6, for example, approximately 100 to 150 μm thick. Thus, the semiconductor device 1, though the stress reducing layer 6 is additionally provided therein, can be made thinner as compared with one in which the thickness of a die pad is increased to reduce damage to a semiconductor chip. That is, the semiconductor device 1, in which damage to the semiconductor chip 2 is reduced, can be formed as a thin package-type semiconductor device. In addition, with the semiconductor device 1 of this embodiment, since the die pad 3 can be made thin, the lead frame 10 can also be made thin, and this gives the lead frame 10 good workability in, for example, bending.

In the semiconductor device 1 of the first embodiment described above, the bottom face of the stress reducing layer 6 is flush with that of the sealing body 7 and is exposed; however, this is not meant to be a limitation, and the stress reducing layer 6 may be completely covered with the sealing body 7 together with the semiconductor chip 2, the die pad 3, and the inner leads 4. This will be described below with reference to the drawings.

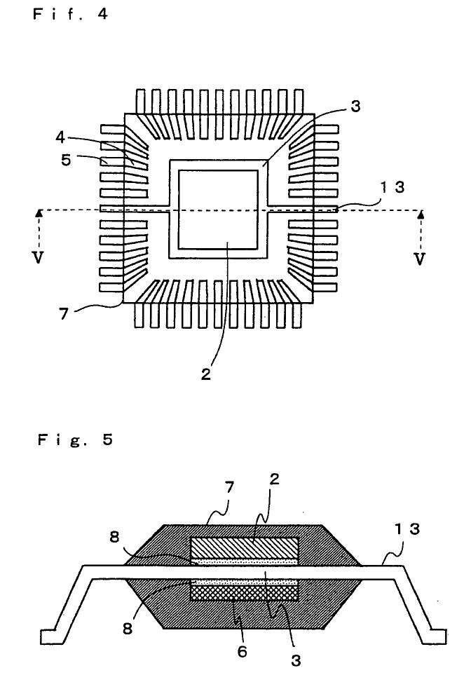

FIGS. 4 and 5 are diagrams showing a modified example of the semiconductor device 1 of the first embodiment; FIG. 4 is a schematic plan view of the semiconductor device as viewed from the semiconductor chip 2 side, and FIG. 5 is a schematic sectional view taken along line V-V of FIG. 4. FIG. 4 is drawn, for convenience of illustration, on the assumption that the sealing resin for sealing the semiconductor chip and other components is transparent. Also, in FIG. 4, for convenience of illustration, the fine metal wires 9 (see FIG. 1) for electrically connecting the semiconductor chip 2 and the inner leads 4 are omitted.

In the case where the stress reducing layer 6 is also completely covered with the sealing body 7 as shown in FIGS. 4 and 5, heat cannot be dissipated from the bottom face of the sealing body 7 as in the semiconductor device 1 of the first embodiment. To cope with this, an extending portion 13 is provided so as to extend from the die pad 3, which is substantially rectangular as viewed in plan, as far as to outside the sealing body 7, so that heat can be dissipated to the printed board (not shown) via this extension portion 13.

In the semiconductor device shown in FIGS. 4 and 5, the die pad 3 is not offset downward with respect to the other parts of the lead frame, unlike in the semiconductor device 1 of the first embodiment. Thus, unlike in the semiconductor device 1, no support bar 11 is provided. However, needless to say, in the semiconductor device shown as a modified example in FIGS. 4 and 5, the support bars 11 may be provided and the die pad 3 may be offset downward with respect to the other parts of the lead frame as necessary.

The materials of the members forming the semiconductor device 1 of the first embodiment described above are only an example, and many modifications and variations are possible within the scope and spirit of the present invention. For example, the lead frame 10 used for fabricating the semiconductor device 1 may be formed with Cu and the like instead of the Cu alloy. The material of the stress reducing layer 6 is not limited to the 42 alloy material, but any material can be used as long as it has a thermal expansion coefficient lower than that of the material mainly forming the die pad 3 (in the semiconductor device 1, the Cu alloy). However, it is preferable that the material have a thermal expansion coefficient that is equal to or close to that of the material mainly forming the semiconductor chip 2 (in the semiconductor device 1, Si). That is, the material of the stress reducing layer 6 may be, for example, a kovar material (an alloy formed by adding nickel, cobalt, etc. to iron; a composition example is: Ni 29%, Co 17%, Si 0.2%, Mn 0.3%, and Fe 53.5%, all by weight), silicon (Si), or the like.

### Second Embodiment

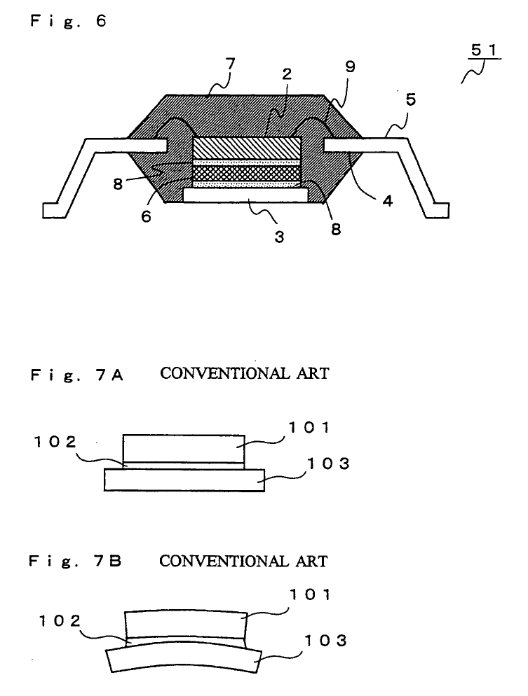

Next, a semiconductor device of a second embodiment of the present invention will be described. FIG. 6 is a schematic sectional view showing the configuration of the semiconductor device of the second embodiment. In the description of the semiconductor device 51 of the second embodiment, such parts as the semiconductor device 51 has in common with the semiconductor device 1 of the first embodiment are identified with the same reference numerals, and overlapping descriptions will not be repeated unless otherwise particularly required.

The semiconductor device 51 is, as the semiconductor device 1 of the first embodiment, a semiconductor device having a quad flat package (QFP). The semiconductor device 51 includes the semiconductor chip 2, the die pad 3, the inner leads 4, the outer leads 5, the stress reducing layer 6, and the sealing body 7. The inner leads 4 are each electrically connected to the semiconductor chip 2 via the fine metal wire 9 such as a gold wire. The inner leads 4 are continuous with the outer leads 5, and part of each outer lead 5 is bent.

In the semiconductor device 51 of the second embodiment, unlike in the semiconductor device 1 of the first embodiment, the stress reducing layer 6 is disposed not on the rear face of the die pad 3 that is opposite to the face of the die pad 3 on which the semiconductor chip 2 is mounted, but on the same side as the semiconductor chip 2 with respect to the die pad 3. That is, the stress reducing layer 6 is bonded to the top face of the die pad 3 via the solder layer 8, and the semiconductor chip 2 is bonded to the top face of the stress reducing layer 6 via the solder layer 8.

In the semiconductor device 51, the die pad 3 is offset downward with respect to the inner leads 4, and its bottom face is flush with that of the sealing body 7. That is, the bottom face of the die pad 3 is exposed, and this facilitates dissipation of heat generated by the semiconductor chip 2.

Next, a fabrication method of the semiconductor device 51 will be described. The fabrication method of the semiconductor device 51 shown here is an example, and needless to say, the semiconductor device 51 may be fabricated by any other fabrication method.

First, a lead frame for fabricating the semiconductor device 51 is prepared. The lead frame here has the same shape as the lead frame 10 (see FIG. 3) of the first embodiment. In this case, also, when the package-type semiconductor device 51 is formed, the die pad 3 supported by the support bars 11 is pressed down by a predetermined amount so that the bottom face of the die pad 3 is flush with that of the sealing body 7 and is exposed.

Then, solder is supplied to the die pad 3 of the lead frame 10, and heat is applied (e.g., at a temperature approximately 350° C.) to melt the solder. Then, on top of the molten solder, the 42 alloy material forming the stress reducing layer 6 is placed, and then the die pad 3 and the 42 alloy material are fixedly bonded together by application of pressure or by other methods. Next, in the heated state, solder is supplied to the top face of the 42 alloy material forming the stress reducing layer 6, and thus molten solder is formed. Then, the semiconductor chip 2 is placed on the molten solder, and the 42 alloy material and the semiconductor chip 2 are fixedly bonded together by application of pressure or by other methods.

After the semiconductor chip 2 is fixedly bonded, the lead frame 10, on which the stress reducing layer 6 and the semiconductor chip 2 are bonded, is cooled down to a predetermined temperature. In this way, the semiconductor chip 2 is bonded to the die pad 3 with the stress reducing layer 6 laid in the solder layer 8. The above described bonding with solder is performed in an atmosphere of, for example, nitrogen gas.

Then, the inner leads 4 are electrically connected to the terminal pad formed on the top face of the semiconductor chip 2 by the fine metal wires 9. Then, the semiconductor chip 2, the die pad 3, the inner leads 4, and the stress reducing layer 6 are covered with the sealing resin (more precisely, the bottom face of the stress reducing layer 6 is not covered with the resin as described above), for example, by a transfer-mold method using a mold, and thus the sealing body 7 is formed.

Lastly, unwanted parts of, for example, the tie bars 12 and the support bar 11 projecting from the sealing body 7 are cut off and removed, and the outer leads 5 that are continuous with the inner leads 4 and disposed outside the sealing body 7 are bent into a predetermined shape, and thus the fabrication of the semiconductor device 51 is completed.

Next, a description will be given of the operation of the semiconductor device 51. In the semiconductor device 51, the stress reducing layer 6 is laid in the solder layer 8 for bonding the semiconductor chip 2 and the die pad 3 together. This stress reducing layer 6 is formed of the 42 alloy member having the thermal expansion coefficient that is close to that of Si mainly forming the semiconductor chip 2 and that is quite smaller than that of the Cu alloy mainly forming the die pad 3. Therefore, in the semiconductor device 51, when the semiconductor chip 2 is bonded to the die pad 3 to be mounted thereon, the stress reducing layer 6 reduces the stress applied to the semiconductor chip due to the difference in thermal shrinkage ratio between the semiconductor chip 2 and the die pad 3, and thus the semiconductor chip 2 can be protected from damage.

Furthermore, in the semiconductor device 51, since the stress reducing layer 6 is laid in the solder layer 8 for bonding the semiconductor chip 2 and the die pad 3 together, it is possible to reduce the stress applied to the semiconductor chip with a high degree of accuracy as compared with the case where the stress applied to the semiconductor chip 2 is reduced by increasing the thickness of the solder layer for bonding the semiconductor chip 2 and the die pad 3 together.

Moreover, although the die pad 3 needs to be approximately 500 μm thick in order to effectively reduce the stress applied to the semiconductor chip 2 due to the solder bonding, in the semiconductor device 51 of this embodiment, when the die pad 3 is approximately 100 to 150 μm thick, the stress applied to the semiconductor chip 2 can be effectively reduced by making the stress reducing layer 6 approximately 100 to 150 μm thick. Therefore, the semiconductor device 51, although it is additionally provided with the stress reducing layer 6, can be more compact as compared with the case where the thickness of the die pad is increased to reduce damage to the semiconductor chip. That is, the semiconductor device 51 can be formed as a thin package-type semiconductor device in which damage to the semiconductor chip 2 is reduced. In addition, with the semiconductor device 51 of this embodiment, since the die pad 3 can be made thin, the lead frame 10 can also be made thin, and this gives the lead frame 10 good workability in, for example, bending.

In the semiconductor device 51 of the second embodiment, the bottom face of the die pad 3 is flush with that of the sealing body 7 and is exposed; however, the die pad 3 may be completely covered with the sealing body 7 together with the semiconductor chip 2, the inner leads 4, and the stress reducing layer 6. In this case, as in the semiconductor device whose configuration is shown in FIGS. 4 and 5 as a modified example of the first embodiment, in order to enhance heat dissipation, it is possible to extend the extending portion 13 from the die pad 3 to dissipate heat by use thereof.

In the semiconductor device 51, the 42 alloy material is used as material of the stress reducing layer 6, but this is not meant to be a limitation. A preferable material of the stress reducing layer 6 is a material having a thermal expansion coefficient that is lower than that of the material mainly forming the die pad 3 (e.g., Cu alloy and Cu) and that is equal or close to that of the material mainly forming the semiconductor chip 2 (e.g., Si). Examples of such a material are a kovar material and silicon.

The first and second embodiments described above deal with semiconductor devices having a quad flat package (QFP). However, this is not meant to limit the present invention in any way, and within the scope of the object of the present invention, the present invention is widely applicable to semiconductor devices having other types of packages such as: a surface-mount type package such as an SOP (small outline package), an SOJ (small outline J-lead package), an SON (small outline non-lead package, a QFJ (quad flat J-lead package), and a QFN (quad flat non-lead package), a lead-insertion type package, and the like.

According to the present invention, it is possible to provide a highly reliable package-type semiconductor device in which a semiconductor chip is protected from damage such as cracks. Furthermore, according to the present invention, since damage to the semiconductor chip can be reduced with a configuration in which the thickness of a die pad on which the semiconductor chip is mounted is reduced, a thin compact package-type semiconductor device can be easily realized. Therefore, the semiconductor device of the present invention is extremely useful as a package-type semiconductor device.

What is claimed is:

1. A semiconductor device, comprising:
a semiconductor chip;
a die pad to which the semiconductor chip is bonded with solder to be mounted thereon;
a plurality of leads electrically conducted to the semiconductor chip;
a stress reducing layer that reduces stress applied to the semiconductor chip and is provided on a rear face of the die pad opposite to a face of the die pad on which the semiconductor chip is mounted; and
a sealing body for sealing at least the semiconductor chip.

2. The semiconductor device of claim 1, wherein
the stress reducing layer is bonded to the rear face of the die pad via a solder layer.

3. The semiconductor device of claim 1, wherein
the stress reducing layer is formed of a material having a smaller thermal expansion coefficient than a main material forming the die pad has.

4. The semiconductor device of claim 2, wherein
the stress reducing layer is formed of a material having a smaller thermal expansion coefficient than the main material forming the die pad has.

5. The semiconductor device of claim 3, wherein
the stress reducing layer is formed of a material having a same or a substantially same thermal expansion coefficient as a main material forming the semiconductor chip has.

6. The semiconductor device of claim 4, wherein
the stress reducing layer is formed of a material having a same or substantially same thermal expansion coefficient as the main material forming the semiconductor chip has.

7. A semiconductor device, comprising:
a semiconductor chip;
a die pad to which the semiconductor chip is bonded with solder to be mounted thereon;
a plurality of leads electrically conducted to the semiconductor chip;
a stress reducing layer that is laid in a solder layer and is formed of a material having a thermal expansion coefficient that is smaller than a thermal expansion coefficient of a main material forming the die pad and is same or substantially same as a thermal expansion coefficient of a main material forming the semiconductor chip; and
a sealing body for sealing at least the semiconductor chip.
